(19) United States
(12) Patent Application Publication
(10) Pub. No.: US 2021/0165511 A1
(43) Pub. Date: Jun. 3, 2021

(54) CONDUCTIVE MATERIAL AND TREATMENT METHOD

(71) Applicant: MITSUBISHI PAPER MILLS LIMITED, Sumida-ku, Tokyo (JP)

(72) Inventors: Norihiko Gokan, Sumida-ku (JP); Naoya Nishimura, Sumida-ku (JP)

(21) Appl. No.: 16/770,975

(22) PCT Filed: Dec. 28, 2018
(86) PCT No.: PCT/JP2018/048550

§ 371 Date: Jun. 9, 2020

(30) Foreign Application Priority Data
Jan. 11, 2018 (JP) 2018-002751
Jun. 6, 2018 (JP) 2018-108717

(51) Int. Cl. G06F 3/041

(52) U.S. Cl. CPC G06F 3/041; G06F 2203/04103

(57) ABSTRACT

The present invention provides a conductive material that is improved in terms of resistance change due to solar radiation exposure. The conductive material has a mesh pattern of metallic silver thin lines on a support, and one surface of the conductive material on the same side as the mesh pattern of metallic silver thin lines is provided with a copper element in an amount of 1 mg/m² or more.

### TECHNICAL FIELD

The present invention relates to a conductive material that is improved in terms of resistance change and a treatment method for such an improvement.

### BACKGROUND ART

In electronic devices, such as smartphones, personal digital assistants (PDAs), laptop PCs, tablet PCs, office automation equipment, medical equipment, and car navigation systems, their display screens are generally equipped with touchscreen sensors as input means.

There are a variety of touchscreen sensors that utilize different position detection technologies, such as optical, ultrasonic, resistive, surface capacitive, and projected capacitive technologies. For display screen applications as mentioned above, a resistive or projected capacitive technology is preferably used. A resistive touchscreen sensor has a configuration in which two sheets of conductive material each having an optically transparent conductive layer on a support face each other via dot spacers. When a force is applied at a point on the touchscreen sensor, the two optically transparent conductive layers contact each other at this point, and a voltage applied to one of the optically transparent conductive layers is measured via the other optically transparent conductive layer. This leads to the detection of the position where the force has been applied. The other type of touchscreen sensor, namely, a projected capacitive touchscreen sensor uses one sheet of conductive material having two optically transparent conductive layers or uses two sheets of conductive material each having a single optically transparent conductive layer. When a finger or the like touches the surface of the touchscreen sensor, the capacitance between the two optically transparent conductive layers changes. The detection of the capacitance change leads to the detection of the finger touch position. Projected capacitive touchscreen sensors are highly durable because of having no movable part and allow simultaneous multipoint detection. For these reasons, projected capacitive touchscreen sensors are widely used for smartphones, tablet PCs, etc.

Optically transparent conductive layers in conventional art are generally made of a conductive film containing a transparent conductive oxide such as ITO (indium tin oxide). For example, Patent Literature 1 discloses a touchscreen sensor member having an optically transparent conductive layer made of a transparent conductor, such as ITO, IZO (indium zinc oxide) or ZnO (zinc oxide).

In recent years, conductive materials having an optically transparent conductive layer having a mesh pattern of metallic silver thin lines are also disclosed. For example, Patent Literature 2 describes various methods for producing a mesh pattern of metallic silver thin lines, which include:

a method comprising printing a mesh pattern with an ink containing silver particles;

a method comprising applying a resin-based coating liquid containing a catalyst for electroless plating by printing, followed by electroless plating;

a subtractive method comprising providing a photoresist layer on a metal layer, forming a resist pattern, and partially etching away the metal layer; and

a method using a silver halide photosensitive material.

Also known are conductive material laminated bodies having an optically transparent conductive layer having a mesh pattern of metallic silver thin lines, an adhesive layer provided on the optically transparent conductive layer, and a functional material provided on the adhesive layer. For example, Patent Literature 3 discloses a laminated body for touchscreens having a touchscreen sensor, an adhesive layer provided on the touchscreen sensor, which layer has a dielectric constant that is less dependent on temperature, and a protective substrate provided on the adhesive layer. The disclosed laminated body is unlikely to malfunction under a wide range of temperature conditions. Such an adhesive layer is generally used to mediate the adhesion between members such as a display device and a touchscreen sensor.

Conductive material laminated bodies as described above are used in various places, for example, in places exposed to solar radiation. However, in the case where a conductive material laminated body is composed of an optically transparent conductive layer having a mesh pattern of metallic silver thin lines and an adhesive layer provided on the optically transparent conductive layer, solar radiation exposure induces a change in the resistance of the optically transparent conductive layer. Therefore, a solution to this problem has been desired.

Several solutions to resistance change of the optically transparent conductive layer due to solar radiation exposure are suggested in literature. Patent Literature 4 discloses a conductive material laminated body characterized in that an undercoat layer provided under an optically transparent conductive layer contains an amino group-containing compound and that an adhesive layer contains a cationic polymerizable photo-curable resin. Patent Literature 5 discloses a conductive material laminated body characterized in that an undercoat layer provided under an optically transparent conductive layer contains an amino group-containing compound and that an adhesive layer contains a resin formed by polymerization using an acylphosphine compound or a trihaloalkyl compound. Patent Literature 6 discloses a method for laminating an optically transparent conductive layer with an interlayer filling material for touch panels containing an acrylic adhesive obtainable by polymerization of acrylic or other monomers having a molecular skeleton with ultraviolet absorbability or optical stability. Patent Literature 7 discloses a film (conductive material laminated body) comprising metal fibers and a resin layer comprising a metal additive such as metal particles or metal oxide particles. Patent Literature 8 discloses a display device (conductive material laminated body) equipped with a capacitive coupling type touch panel input device comprising an optically transparent conductive layer containing metal nanowires and a light transmission layer that transmits a visible light having a wavelength of a certain value or higher. Furthermore, Patent Literature 9 discloses the use of a transition metal salt or coordination complex of Fe(II), Fe(III), Co(II), Co(III), Mn(II) or the like as a light stabilizer. However, there is still a desire for solutions to resistance change of the optically transparent conductive layer due to solar radiation exposure.

In the meanwhile, regarding methods for depositing a metallic element on a support, electroless plating is known. In copper strike plating, which is a type of electroless thin copper plating, the lower limit of the amount of plating generally corresponds to a plating thickness of 0.01 μm or more and a plating weight of about 90 mg/m² or more as described in Patent Literature 10.

In addition, regarding conductive materials having a metallic element on a support, in the case of a transparent conductive film having a layer formed of metal particles by coating, the lower limit of the coating weight of the metal particles is generally 50 mg/m² or more as described in Patent Literature 11.

### CITATION LIST

### Patent Literature

Patent Literature 1: JP-A 2015-32183

Patent Literature 2: JP-A 2015-133239

Patent Literature 3: JP-A 2014-198811

Patent Literature 4: JP-A 2015-58662

Patent Literature 5: JP-A 2015-106500

Patent Literature 6: JP-A 2016-210916

Patent Literature 7: JP-A 2016-1608

Patent Literature 8: JP-A 2016-21170

Patent Literature 9: WO 2015/143383

Patent Literature 10: JP-A 2015-187303

Patent Literature 11: JP-A 2001-256834

### SUMMARY OF INVENTION

### Technical Problem

An object of the present invention is to provide a conductive material that is improved in terms of resistance change due to solar radiation exposure and a treatment method for obtaining the conductive material. Another object of the present invention is to provide a treatment method that can reduce not only the aforementioned resistance change but also ion migration.

### Solution to Problem

The aforementioned objects of the present invention are achieved by the following.

(1) A conductive material having a mesh pattern of metallic silver thin lines on a support, one surface of the conductive material on the same side as the mesh pattern of metallic silver thin lines being provided with a copper element in an amount of 1 mg/m² or more.
(2) A treatment method for obtaining the conductive material according to claim 1, the method comprising treating, with a treatment liquid containing a copper metal salt, one surface of a conductive material in which a mesh pattern of metallic silver thin lines is provided on a support, the surface being on the same side as the mesh pattern of metallic silver thin lines.
(3) The treatment method according to claim 2, wherein the treatment liquid containing a copper metal salt further contains a hydroxy acid.

### Advantageous Effects of Invention

The present invention provides a conductive material that is improved in terms of resistance change due to solar radiation exposure and a treatment method for obtaining the conductive material. The present invention also provides a treatment method that can reduce not only the aforementioned resistance change but also ion migration.

### BRIEF DESCRIPTION OF DRAWINGS

FIG. 1 shows a schematic view of a positive transparent original used in the Examples.

FIG. 2 shows a schematic view of the conductive material A produced in the Examples.

### DESCRIPTION OF EMBODIMENTS

Hereinafter, the present invention will be described. The conductive material of the present invention has a mesh pattern of metallic silver thin lines on a support, and one surface of the conductive material on the same side as the mesh pattern of metallic silver thin lines is provided with a copper element in an amount of 1 mg/m² or more.

The copper element in the present invention is present in an ionic, salt, or colloidal form on the support surface on the same side as the mesh pattern of metallic silver thin lines and on the thin line surface of the mesh pattern of metallic silver thin lines. In addition, the amount of the copper element on the surface of the conductive material on the same side as the mesh pattern of metallic silver thin lines is 1 mg/m² or more. These are required to reduce resistance change of the optically transparent conductive layer due to solar radiation exposure. While the amount of the copper element is 1 mg/m² or more, the amount of the copper element is preferably 15 mg/m² or less. This is because a further increase in the amount of the copper element produces no further beneficial effects, is just wasteful, and deteriorates in optical properties (haze, total light transmittance, etc.) due to copper coloring of the support. The amount of the copper element is more preferably 10 mg/m² or less.

The conductive material can be produced by treating a conductive material in which a mesh pattern of metallic silver thin lines is provided on a support using the treatment liquid described below.

### Treatment Liquid Containing a Copper Metal Salt

In the treatment liquid containing a copper metal salt, the copper metal salt is exemplified by water-soluble inorganic copper salts such as copper sulfate, copper nitrate, and copper chloride; and water-soluble organic copper salts such as copper formate and copper acetate. One of these copper metal salts alone or a mixture of two or more of them may be used.

The amount of the copper metal salt contained in the treatment liquid is preferably 0.0001 mol/L or more for effective reduction in resistance change of the optically transparent conductive layer of the conductive material due to solar radiation exposure. More preferably, the amount of the copper metal salt contained in the treatment liquid is 0.0003 mol/L or more. In addition, the amount of the copper metal salt contained in the treatment liquid is preferably 0.4 mol/L or less. This is because a further increase in the amount of the copper metal salt produces no further beneficial effects, is just wasteful, and prolongs the time to dissolution of the copper metal salt. The amount of the copper metal salt contained in the treatment liquid is more preferably 0.1 mol/L or less.

The pH of the treatment liquid containing a copper metal salt is not particularly limited, but pH 2 to 9 is preferred for effective reduction in resistance change of the optically transparent conductive layer of the conductive material due to solar radiation exposure. For pH adjustment, the treatment liquid containing a copper metal salt may contain a pH adjuster, such as hydrochloric acid, sulfuric acid, acetic acid, sodium hydroxide, potassium hydroxide, a phosphate, a carbonate, or an ammonium salt. The treatment liquid containing a copper element in the present invention may further contain a known additive, such as a surfactant, a defoamer, an antifoamer, a thickener, or a preservative, if needed in addition to the pH adjuster.

On the other hand, it is undesirable that the treatment liquid containing a copper metal salt contains a complexing agent or a brightener because they hinder effective reduction in resistance change of the optically transparent conductive layer of the conductive material due to solar radiation exposure.

The complexing agent refers to a component that is effective for preventing the precipitation of metal salts in general electroless plating solutions and for preventing the degradation of plating bath components to maintain an adequate plating metal deposition rate. The complexing agent includes various kinds of complexing agents used in known electroless plating solutions. Specific examples of the complexing agent include oxycarboxylic acids such as tartaric acid and malic acid, and soluble salts thereof; amino compounds such as ethylenediamine and triethanolamine; ethylenediamine derivatives such as ethylenediamine tetraacetic acid (EDTA), Versenol (N-hydroxyethylethylenediamine-N,N′,N′-triacetic acid), and Quadrol (N,N,N′,N′-tetrahydroxyethylethylenediamine), and soluble salts thereof; and phosphonic acids such as 1-hydroxyethane-1,1-diphosphonic acid and ethylenediamine tetra(methylenephosphonic acid), and soluble salts thereof.

The brightener refers to a component of general electroplating solutions that is effective for providing a gloss finish on a metal-plated surface. The brightener includes various kinds of brighteners used in known electroplating solutions. For example, organic thiocompounds, oxygen-containing high-molecular organic compounds, and the like are known. Specific examples of the organic thiocompound include 3-mercaptopropanesulfonic acid and a sodium salt thereof; bis-(3-sulfopropyl)disulfide and a disodium salt thereof; and N,N-dimethyldithiocarbamic acid (3-sulfopropyl) ester and a sodium salt thereof. Specific examples of the oxygen-containing high-molecular organic compound include oxyalkylene polymers, polyethylene glycol, polypropylene glycol, and ethyleneoxide-propyleneoxide copolymers.

In the present invention, the treatment liquid containing a copper metal salt preferably further contains a hydroxy acid. Using such a treatment liquid, a treatment method that can reduce not only resistance change due to solar radiation exposure but also ion migration can be provided.

Examples of the hydroxy acid contained in the treatment liquid containing a copper metal salt include glycolic acid, lactic acid, tartronic acid, glyceric acid, leucine acid, malic acid, tartaric acid, gluconic acid, citric acid, isocitric acid, mevalonic acid, pantoic acid, ricinoleic acid, quinic acid, salicylic acid, cresotic acid (homosalicylic acid, hydroxy(methyl) benzoic acid), vanillic acid, syringic acid, hydroxypentanoic acid, hydroxyhexanoic acid, hydroxyheptanoic acid, hydroxyoctanoic acid, hydroxynonanoic acid, hydroxydecanoic acid, hydroxyundecanoic acid, hydroxydodecanoic acid, hydroxytridecanoic acid, hydroxytetradecanoic acid, hydroxypentadecanoic acid, hydroxyheptadecanoic acid, hydroxyoctadecanoic acid, hydroxynonadecanoic acid, hydroxyicosanoic acid, ricinoleic acid, pyrocatechuic acid, resorcylic acid, protocatechuic acid, gentisic acid, orsellinic acid, gallic acid, mandelic acid, benzilic acid, atrolactinic acid, melilotic acid, phloretic acid, coumaric acid, umbellic acid, caffeic acid, ferulic acid, sinapinic acid, and salts thereof. Among these hydroxy acids, aliphatic hydroxy acids and salts thereof are preferable because they are more effective for preventing the decrease in the reliability of the conductive material due to ion migration between mesh patterns of metallic silver thin lines. More preferred are citric acid and tartaric acid and salts thereof, and particularly preferred are citric acid and a salt thereof. One of these hydroxy acids alone or a mixture of two or more of them may be used.

The amount of the hydroxy acid contained in the treatment liquid containing a copper metal salt is preferably 0.0002 mol/L or more for effective prevention of the decrease in the reliability of the conductive material due to ion migration between mesh patterns of metallic silver thin lines. More preferably, the amount of the hydroxy acid contained in the treatment liquid is 0.002 mol/L or more. In addition, the amount of the hydroxy acid contained in the treatment liquid containing a copper metal salt is preferably 0.4 mol/L or less. This is because a further increase in the amount of the hydroxy acid produces no further beneficial effects, is just wasteful, and prolongs the time to dissolution of the hydroxy acid. The amount of the hydroxy acid contained in the treatment liquid containing a copper metal salt is more preferably 0.1 mol/L or less.

Treatment with Treatment Liquid Containing a Copper Metal Salt

There is no particular limitation on the method for treating a conductive material in which a mesh pattern of metallic silver thin lines is provided on a support using the treatment liquid containing a copper metal salt. The surface of such a conductive material on the same side as the mesh pattern of metallic silver thin lines is brought into contact with the treatment liquid containing a copper metal salt. Specific examples of the treatment method can be as follows:

the conductive material is immersed in the treatment liquid containing a copper metal salt;

any known coating technique such as a bar coating technique, a spin coating technique, a die coating technique, a blade coating technique, a gravure coating technique, a curtain coating technique, a spray coating technique, or a kiss coating technique is employed to apply the treatment liquid containing a copper metal salt onto one surface of a conductive material in which a mesh pattern of metallic silver thin lines is provided on a support, which surface is on the same side as the mesh pattern; and

any known printing technique such as gravure printing, flexographic printing, ink jet printing, screen printing, offset printing, gravure offset printing, dispenser printing, or pad printing is employed to apply the treatment liquid containing a copper metal salt onto one surface of a conductive material in which a mesh pattern of metallic silver thin lines is provided on a support, which surface is on the same side as the mesh pattern.

Among these methods, preferred is a method in which the conductive material is immersed in the treatment liquid containing a copper metal salt. This is because of its ease of achieving the contact of the surface of a fine mesh pattern of metallic silver thin lines with the treatment liquid containing metal salt.

In the present invention, the duration of contact with the treatment liquid containing a copper metal salt is preferably 1 second or more so that the amount of the copper element on the surface of the conductive material on the same side as the mesh pattern of metallic silver thin lines reaches 1 mg/m² or more. This enables effective reduction in resistance change of the optically transparent conductive layer. The contact duration is more preferably 3 seconds or more, and particularly preferably 5 seconds or more. In addition, the upper limit of the duration for which the surface of the conductive material on the same side as the mesh pattern of metallic silver thin lines is in contact with the treatment liquid containing a copper metal salt is preferably 10 minutes or less. The temperature of the treatment liquid containing a copper metal salt during the contact with the surface of the conductive material on the same side as the mesh pattern of metallic silver thin lines is not particularly limited. For effective reduction in resistance change of the optically transparent conductive layer, 10° C. or more is preferred, and 30° C. or more is more preferred. In addition, the upper limit of the temperature is preferably 70° C. or less.

### Water Washing

After the conductive material in which a mesh pattern of metallic silver thin lines is provided on a support is treated with the treatment liquid containing a copper metal salt as described above, the conductive material is preferably washed with water for the purpose of removing an excess of the treatment liquid containing an copper metal salt. The water washing prevents deterioration in the optical properties (haze, total light transmittance, etc.) due to the treatment liquid left on the surface of the conductive material. The water washing may be performed using an aqueous wash solution composed of water only, an aqueous wash solution containing a pH adjuster such as a phosphate or a carbonate, or an aqueous wash solution containing a preservative used for preventing spoilage.

The method for water washing is not particularly limited, and examples include spraying a shower of an aqueous wash solution using a scrubbing roller or the like, and jet spraying an aqueous wash solution from a nozzle or the like. A plurality of shower devices and/or nozzles can be used for more efficient removal. Alternatively, the conductive material may be immersed in an aqueous wash solution. After water washing, the conductive material is preferably subjected to heating or air drying for removal of the residual moisture thereon.

### Conductive Material

The support of the conductive material of the present invention is not particularly limited. In the case where the conductive material is used for touchscreen sensors and other devices that have to transmit light, the conductive material is required to be transparent and therefore particularly preferably has an optically transparent support. Examples of the optically transparent support include films made of a polyolefin resin, such as polyethylene or polypropylene, a vinyl-chloride resin, such as polyvinyl chloride or a vinyl chloride copolymer, an epoxy resin, a polyarylate, a polysulfone, a polyether sulfone, a polyimide, a fluorine resin, a phenoxy resin, triacetyl cellulose, polyethylene terephthalate, a polyimide, polyphenylene sulfide, polyethylene naphthalate, a polycarbonate, an acrylic resin, cellophane, nylon, a polystyrene resin, an ABS resin, or the like; and glasses, such as quarts glass and alkali-free glass. The total light transmittance of the support is preferably 60% or more, and particularly preferably 70% or more. The haze of the support is preferably 0 to 3% for high transparency of the conductive material, and particularly preferably 0 to 2%. On a surface of the support, whether on the same side as or on the opposite side from the optically transparent conductive layer, a publicly known layer, such as an adhesion-promoting layer, a hardcoat layer, an anti-reflection layer, an anti-glare layer, or a layer containing a non-metal conductive material, such as ITO or polythiophene, may be provided.

Regarding the metal composition of the metallic silver thin lines in the mesh pattern of metallic silver thin lines in the present invention, the mass proportion of silver relative to the total amount of the metals is preferably 50% by mass or more, more preferably 80% by mass or more, and particularly preferably 90% by mass or more. The mass proportion of a binder component in the metallic silver thin lines is preferably less than 20% by mass, and more preferably less than 10% by mass. Metallic silver thin lines are highly conductive, but they entail a substantial change in resistance due to solar radiation exposure and a substantial decrease in the reliability of the conductive material due to ion migration between mesh patterns of metallic silver thin lines, as described in the section of the “BACKGROUND ART”. The present invention is particularly effective for solving such problems.

The method for producing the mesh pattern of metallic silver thin lines on a support is not particularly limited. For example, the following methods can be used:

a method for producing a mesh pattern of metallic silver thin lines, which method includes applying a conductive metal ink or a conductive paste containing a metal and a binder onto a support by printing or other techniques according to the procedure disclosed in JP-A 2015-69877;

a method for producing a mesh pattern of metallic silver thin lines, which method includes using tanning development and a conductive material precursor, which is a silver halide photosensitive material having a silver halide emulsion layer on a support, according to the procedure disclosed in JP-A 2007-59270;

a method for producing a mesh pattern of metallic silver thin lines, which method includes using direct development and a conductive material precursor, which is a silver halide photosensitive material having a silver halide emulsion layer on a support, according to any of the procedures disclosed in JP-A 2004-221564, JP-A 2007-12314, etc.;

a method for producing a mesh pattern of metallic silver thin lines by the so-called silver halide diffusion transfer process, which process includes subjecting a conductive material precursor, which is a silver halide photosensitive material at least having a physical development nuclei layer and a silver halide emulsion layer in this order on a support, to a reaction with a soluble silver halide-forming agent and a reducing agent in an alkaline liquid, according to any of the procedures disclosed in JP-A2003-77350, JP-A2005-250169, JP-A 2007-188655, JP-A 2004-207001, etc.;

a method for producing a mesh pattern of metallic silver thin lines, which method includes preparing a conductive material precursor, which is a photosensitive resist material having an undercoat layer and a photosensitive resist layer in this order on a support, pattern-wise exposing and developing the photosensitive resist layer to form a resist image, depositing a metal by electroless plating on the part of the undercoat layer uncovered by the resist image, and removing the resist image, according to the procedure disclosed in JP-A 2014-197531;

a method for producing a mesh pattern of metallic silver thin lines, which method includes forming a metallic film and a resist film in this order on a support, exposing and developing the resist film to form through-holes therein, and etching away the metallic film at the bottom of the through-holes, according to the procedure disclosed in JP-A 2015-82178; and

a method for producing a mesh pattern of metallic silver thin lines, which method includes forming a layer containing metal nanowires on a support and patterning the layer according to the procedure disclosed in JP-A 2012-28183.

Among these methods, preferred are the method using a silver halide photosensitive material as a conductive material precursor and the method using a photosensitive resist material as a conductive material precursor because of their ease of producing a mesh pattern of metal thin lines containing silver, a highly conductive metal. Particularly preferred is a method based on the silver halide diffusion transfer process using a silver halide photosensitive material as a conductive material precursor because of its ease of thinning metallic silver lines.

In the present invention, the optically transparent conductive layer may have been subjected to a known metal-surface treatment before or after the treatment with the treatment liquid containing a copper metal salt. For example, the following methods may be used:

treatment with a reducing substance, a water-soluble phosphorus oxoacid compound, and/or a water-soluble halogenated compound as described in JP-A 2008-34366;

treatment with a triazine having two or more mercapto groups in the molecule or a derivative thereof as described in JP-A 2013-196779; and

blackening treatment based on sulfuration as described in JP-A 2011-209626.

In the case where a silver halide photosensitive material is used as a conductive material precursor to form an optically transparent conductive layer having a mesh pattern of metallic silver thin lines, the optically transparent conductive layer may be treated with a treatment liquid containing an enzyme such as proteinase, as described in JP-A 2007-12404, to reduce the residual amount of gelatin etc. This treatment leads to an enhanced adhesion of the optically transparent conductive layer to an adhesive layer.

In the case where the conductive material of the present invention is used for touchscreen sensors, the mesh pattern of metallic silver thin lines preferably forms the optically transparent conductive layer and is preferably a geometric pattern formed of a plurality of unit lattices arranged in a grid-like manner in terms of sensor sensitivity, sensor pattern visibility (low visibility), etc. Examples of the shape of the unit lattice include triangles, such as an equilateral triangle, an isosceles triangle, and a right triangle; quadrangles, such as a square, a rectangle, a lozenge, a parallelogram, and a trapezoid; n-sided polygons, such as a hexagon, an octagon, a dodecagon, and an icosagon; and a star. One of these shapes may be used repeatedly, and alternatively, two or more of these shapes may be used in combination. Among these shapes of the unit lattice, a square and a lozenge are particularly preferred. In addition, irregular geometric patterns, which are typified by the Voronoi diagram, the Delaunay diagram, the Penrose tiling, etc., are also preferred as the mesh pattern of metallic silver thin lines.

In the case where the conductive material of the present invention is used for touchscreen sensors, the optically transparent conductive layer preferably has a plurality of sensor parts serving as sensors each formed of a mesh pattern of metallic silver thin lines. In addition, the optically transparent conductive layer may also have dummy parts, which are electrically insulated from the sensors, for the purpose of reducing the visibility of the sensor parts (low visibility of the sensor parts). Further, the optically transparent conductive layer may also have, in addition to the sensor parts and the dummy parts, a terminal part configured to transmit electric signals to the outside and/or a peripheral wire part electrically connecting the sensor part to the terminal part. The terminal part and the peripheral wire part may be formed of a mesh pattern of metallic silver thin lines or a fill pattern.

In the present invention, the line width of each of the metallic silver thin lines forming the mesh pattern is preferably 1.0 to 20 μm for good balance between optical transparency and conductivity, and is more preferably 1.5 to 15 μm. In the case where the mesh pattern of metallic silver thin lines is a geometric pattern in which unit lattices are arranged in a grid-like manner, the repeat distance of the unit lattice is preferably 100 to 1000 μm, and more preferably 100 to 400 μm.

On a surface of the conductive material of the present invention, whether the surface may be on the same side as the mesh pattern of metallic silver thin lines or on the opposite side, a functional material can be provided via an adhesive layer to produce a conductive material laminated body. The adhesive layer means a layer containing a known adhesive such as a rubber adhesive, an acrylic adhesive, a silicone adhesive, or a urethane adhesive. The thickness of the adhesive layer is preferably 5 to 500 μm for high transparency of the conductive material laminated body, and is more preferably 10 to 250 μm. For the same purpose, the total light transmittance of the adhesive layer is preferably 90% or more, particularly preferably 95% or more; and the haze of the adhesive layer is preferably 0 to 3%, particularly preferably 0 to 2%.

The adhesive layer may be formed by using any of the following: adhesive tapes for optical use containing highly transparent acrylic adhesives, as illustrated in JP-A 9-251159, JP-A 2011-74308, etc.; and cured materials from highly transparent curable resins, as illustrated in JP-A 2009-48214, JP-A 2010-257208, etc. Adhesive tapes for optical use and highly transparent curable resins are commercially available. Commercially available adhesive tapes for optical use include optically clear adhesive tapes from 3M Japan Limited (then Sumitomo 3M Limited) (8171CL/8172CL/8146-1/8146-2/8146-3/8146-4, etc.); and optically clear adhesive tapes from NITTO DENKO CORPORATION (LUCIACS (registered trademark) CS9622T/CS9862UA, etc.). Commercially available cured materials include optical elastic resin SVR (registered trademark) series (SVR1150, SVR1320, etc.) from Dexerials Corporation; WORLD ROCK (registered trademark) series (HRJ (registered trademark)-46, HRJ-203, etc.) from Kyoritsu Chemical & Co., Ltd.; and UV light-curable optically clear adhesives Loctite (registered trademark) LOCA series (Loctite 3192, Loctite 3193, etc.) from Henkel Japan Ltd. These products can be purchased and used.

Examples of the functional material include the conductive material of the present invention; glasses such as chemically strengthened glass, sodium glass, quarts glass, and alkali-free glass; films containing resins such as polyethylene terephthalate; and materials in which at least one surface of any of these glasses or films is provided with a known functional layer such as a hardcoat layer, an anti-reflection layer, an anti-glare layer, a polarizing layer, or an ITO conductive film.

### Examples

Hereinafter, the present invention will be described in more detail with reference to the following examples, but the present invention is not limited thereto and can be embodied in various forms within the technical scope of the invention.

### Production of Conductive Material 1

A polyethylene terephthalate film having a thickness of 100 μm was used as a support. The total light transmittance and the haze of the support was 91.8% and 0.7%, respectively.

Next, a physical development nuclei layer-forming coating liquid having the composition shown below was uniformly applied onto the support by gravure coating and dried to forma physical development nuclei layer.

### Preparation of Palladium Sulfide Sol

| | | | |
|---|---|---|---|
| Liquid A | Palladium chloride | 5 | g |
| | Hydrochloric acid | 40 | mL |
| | Distilled water | 1000 | mL |
| Liquid B | Sodium sulfide | 8.6 | g |
| | Distilled water | 1000 | mL |

Liquid A and Liquid B were mixed with stirring, and after 30 minutes, passed through a column filled up with an ion exchange resin to give a palladium sulfide sol.

### Physical Development Nuclei Layer-Forming Coating Liquid Per m²

| | | |
|---|---|---|
| Palladium sulfide sol prepared above | 0.4 | mg |
| (solid content) | | |
| 2% by mass aqueous glyoxal solution | 200 | mg |
| Surfactant (S-1) | 4 | mg |
| Denacol (registered trademark) EX-830 | 25 | mg |
| (polyethylene glycol diglycidyl ether | | |
| manufactured by Nagase ChemteX | | |
| Corporation | | |
| 10% by mass aqueous solution of EPOMIN | 500 | mg |
| (registered trademark) HM-2000 | | |
| (polyethyleneimine manufactured by | | |
| Nippon Shokubai Co., Ltd.; average | | |
| molecular weight: 30,000) | | |

[Chem. 1]
S-1

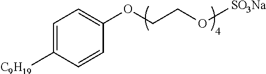

Subsequently, an intermediate layer, a silver halide emulsion layer, and a protective layer, of which the compositions are shown below, were uniformly applied in this order (from closest to the support) onto the physical development nuclei layer by slide coating and dried to give a conductive material precursor. A silver halide emulsion contained in the silver halide emulsion layer was prepared by a controlled-double jet method. The silver halide contained in the silver halide emulsion was composed of 95 mol % silver chloride and 5 mol % silver bromide, and silver halide particles had an average particle diameter adjusted to 0.15 μm. The silver halide particles were subjected to gold-sulfur sensitization using sodium thiosulfate and chloroauric acid by the usual method. The thus-obtained silver halide emulsion contained 0.5 g of gelatin per gram of silver as a protective colloid (binder).

### Composition of Intermediate Layer Per m²

| | |
|---|---|
| Gelatin | 0.5 g |
| Surfactant (S-1) | 5 mg |
| Dye 1 | 5 mg |

[Chem. 2]
Dye 1

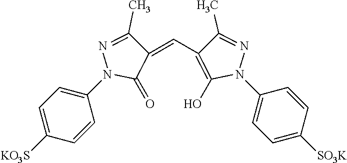

### Composition of Silver Halide Emulsion Layer Per m²

| | |
|---|---|
| Silver halide emulsion | Equivalent of 3.0 g |
| | of silver |
| 1-Phenyl-5-mercapto-tetrazole | 3 mg |
| Surfactant (S-1) | 20 mg |

### Composition of Protective Layer Per m²

| | | |
|---|---|---|
| Gelatin | 1 | g |
| Amorphous silica matting agent | 10 | mg |
| (average particle diameter: 3.5 μm) | | |
| Surfactant (S-1) | 10 | mg |

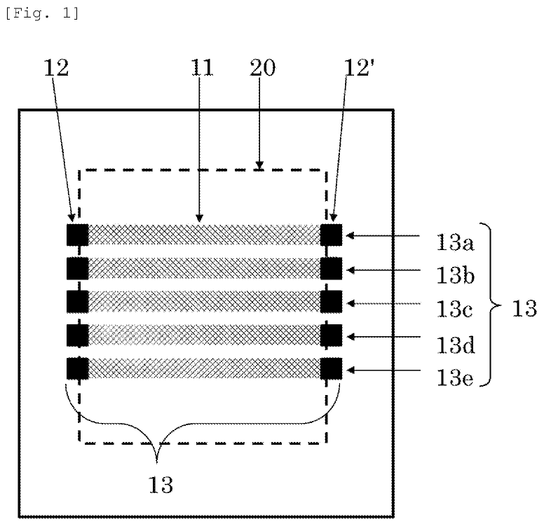

The conductive material precursor was brought into close contact with the positive transparent original shown in FIG. 1 and exposed to light through a resin filter which cuts off light of 400 nm or less in wavelength using a contact printer with a mercury lamp as a light source. The positive transparent original has test patterns 13 (13a to 13e, 5 bars in total) each composed of a mesh pattern 11 and fill patterns 12 and 12′. The fill patterns 12 and 12′ of the test pattern 13 are connected via the mesh pattern 11, which is composed of lozenge-shaped unit lattices each having a line width of 5.0 μm, a side length of 300 μm, and a smaller angle of 60°. In the figure, the dashed line surrounds an area 20 to be laminated with a functional material described later. The light exposure was followed by immersion in the diffusion transfer developer described below at 20° C. for 60 seconds. Finally, the silver halide emulsion layer, the intermediate layer, and the protective layer were washed off with warm water at 40° C., and drying was performed. Thus, a conductive material 1 was obtained. The pattern of the obtained conductive material 1 had the same shape and line width, etc. as those of the positive transparent original.

### Composition of Diffusion Transfer Developer

| | |
|---|---|
| Potassium hydroxide | 25 g |
| Hydroquinone | 18 g |
| 1-Phenyl-3-pyrazolidone | 2 g |
| Potassium sulfite | 80 g |
| N-methylethanolamine | 15 g |
| Potassium bromide | 1.2 g |

The total volume was adjusted to 1000 mL with water, and the pH was adjusted to 12.2.

### Production of Conductive Materials 2 to 9

Sheets of the conductive material 1 obtained as described above were separately immersed in metal salt-containing treatment liquids 1 to 8 shown in Table 1, which contained their respective metal salts in ion exchanged water. The duration and temperature of the immersion was 1 minute and 40° C., respectively. Excess metal salt-containing treatment liquid was washed off with a shower of water. After drying, conductive materials 2 to 9 were obtained. The pH of each metal salt-containing treatment liquid used was adjusted beforehand to 5.0 with ammonium chloride. The amount of the metallic element of each of the conductive materials 2 to 9 as measured by X-ray fluorescence spectrometry is shown in Table 2. The measurement was performed in two areas, i.e., a mesh pattern area and a non-image area, which has no mesh pattern. There was no significant difference between the two areas in any of the conductive materials.

### Production of Conductive Materials 10 and 11

Metal salt-containing treatment liquids 9 and 10 shown in Table 1, which contained their respective metal salts in ion exchanged water, were uniformly applied onto separate sheets of the conductive material 1 by slide coating such that the amount of the metallic element after drying was 8 mg/m². After drying, conductive materials 10 and 11 were obtained.

### Production of Conductive Materials 12 and 13

Metal salt-containing treatment liquids 9 and 10 shown in Table 1, which contained their respective metal salts in ion exchanged water, were uniformly applied onto separate sheets of the conductive material 1 by slide coating such that the amount of the metallic element after drying was 13 mg/m². After drying, conductive materials 12 and 13 were obtained.

### Production of Conductive Materials 14 and 15

Metal salt-containing treatment liquids 9 and 10 shown in Table 1, which contained their respective metal salts in ion exchanged water, were uniformly applied onto separate sheets of the conductive material 1 by slide coating such that the amount of the metallic element after drying was 18 mg/m². After drying, conductive materials 14 and 15 were obtained.

TABLE 1

| Metal | | |
|---|---|---|
| salt-containing | | Metal salt |
| treatment | | concentration |
| liquid | Metal salt | (mol/liter) |
| 1 | Copper sulfate pentahydrate | 0.0004 |
| 2 | Iron chloride tetrahydrate | 0.0004 |
| 3 | Tin chloride dihydrate | 0.0004 |
| 4 | Cobalt acetate tetrahydrate | 0.0004 |
| 5 | Nickel chloride hexahydrate | 0.0004 |
| 6 | Hydrogen tetrachloroaurate tetrahydrate | 0.0004 |
| 7 | Zinc sulfate heptahydrate | 0.0004 |
| 8 | Aluminum sulfate 14-18 hydrate | 0.0004 |
| 9 | Copper sulfate pentahydrate | 0.012 |
| 10 | Iron chloride tetrahydrate | 0.012 |

### Production of Laminated Bodies

On a sheet of each of the conductive materials 1 to 15, a 100-μm-thick adhesive layer was formed by laminating the sheet with the optically clear adhesive tape 8146-4 manufactured by 3M Japan Limited (then Sumitomo 3M Limited) on the area 20 to be laminated with a functional material. Subsequently, the adhesive layer was laminated with EAGLE XG (registered trademark) (alkali-free glass manufactured by Corning Japan Incorporated) as a functional material. Thus, a laminated body of each conductive material was produced.

### Resistance Evaluation

The resistances between the fill patterns 12 and 12′ for the 5 test patterns 13a to 13e on each laminated body were measured to determine the initial resistances Ra to Re (unit: kΩ) for the test patterns 13a to 13e. Next, each laminated body was exposed to 1000 hour-irradiation of xenon lamp light (its spectral distribution is similar to that of sunlight) using the xenon weather meter NX15 manufactured by Suga Test Instruments Co., Ltd. The irradiation conditions were set according to JIS K7350-2 and as follows: an irradiance of 60 W/m² (wavelength of 300 nm to 400 nm), a chamber temperature of 38° C., a chamber humidity of 50% RH, and a black panel temperature of 63° C. After irradiation, the resistances for the 5 test patterns 13a to 13e on each laminated body were measured again to determine the resistances R′a to R′e (unit: kΩ). The percent change in resistance (unit: %) before and after the irradiation of xenon lamp light on each of the test patterns (13a to 13e) was calculated by the formula shown below. The percent changes in resistance for the individual test patterns 13a to 13e were averaged to determine the average percent change in resistance (unit: %) for each of the conductive materials 1 to 15. The results are shown in Table 2. When the percent change in resistance (unit: %) for the test pattern 13x is represented by Rav., Rav. is given by the following formula:

Rav.={(R′x−Rx)/Rx}×100

(in the formula, x represents any of a to e).

TABLE 2

| | | | Average | |
|---|---|---|---|---|
| | Metal | Amount of | percent | |
| | salt-containing | metallic | change in | |
| Conductive | treatment | element | resistance | |
| material | liquid | (mg/m²) | (%) | Remarks |
| 1 | | | +28.3 | Comparative Example |
| 2 | 1 | 3 | +1.4 | Example |
| 3 | 2 | 3 | +2.1 | Comparative Example |
| 4 | 3 | 3 | +2.1 | Comparative Example |
| 5 | 4 | 3 | +7.1 | Comparative Example |
| 6 | 5 | 3 | +9.2 | Comparative Example |
| 7 | 6 | 3 | +27.8 | Comparative Example |
| 8 | 7 | 3 | +29.7 | Comparative Example |
| 9 | 8 | 3 | +27.9 | Comparative Example |
| 10 | 9 | 8 | +1.5 | Example |
| 11 | 10 | 8 | +2.0 | Comparative Example |
| 12 | 9 | 13 | +1.3 | Example |
| 13 | 10 | 13 | +2.2 | Comparative Example |
| 14 | 9 | 18 | +1.4 | Example |
| 15 | 10 | 18 | +2.1 | Comparative Example |

The results in Table 2 demonstrate the effectiveness of the present invention.

The same procedure as described in the production of the conductive material 2 was performed to give a conductive material 2′ except for using copper acetate monohydrate instead of copper sulfate pentahydrate in the metal salt-containing treatment liquid 1. The resistance for the conductive material 2′ was evaluated in the same manner as for the conductive materials 1 to 15. The results were the same as those for the conductive material 2.

### Production of Conductive Material A

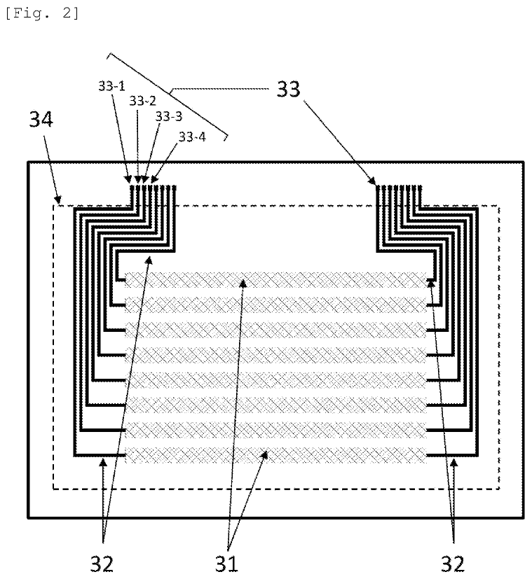

The conductive material precursor described above was brought into close contact with a positive transparent original having a thin-line mesh pattern, a peripheral wire pattern, and a terminal pattern, and exposed to light through a resin filter which cuts off light of 400 nm or less in wavelength using a contact printer with a mercury lamp as alight source. The light exposure was followed by immersion in the diffusion transfer developer described above at 20° C. for 60 seconds. Finally, the silver halide emulsion layer, the intermediate layer, and the protective layer were washed off with warm water at 40° C., and drying was performed. Thus, a conductive material A, which is shown in FIG. 2, was obtained.

### Configuration of Conductive Material A

In the conductive material A, sensor parts 31 (8 bars in the center of the figure), peripheral wires 32 (8 wires each on the right and left sides of the figure), and terminals 33 (8 terminals each on the right and left sides of the figure) collectively correspond to a conductive metallic silver thin line pattern. Each of the sensor parts 31 in the conductive material A is formed of a mesh pattern of metallic silver thin lines, and the mesh pattern is composed of lozenge-shaped unit lattices each having a line width of 4.5 μm, a side length of 300 μm, and a smaller angle of 60°. The peripheral wires 32 and the terminals 33 are all formed of a fill pattern. The line width of each peripheral wire 32 is 20 μm, and the minimum distance between adjacent peripheral wires is 20 μm. These values were all equal to those of the positive transparent original described above. The results of the observation using a confocal microscope (manufactured by Lasertec Corporation, OPTELICS (registered trademark) C130) showed that the thickness of the mesh pattern of metallic silver thin lines forming each sensor part 31 and the thickness of each peripheral wire 32 and each terminal 33 were all 0.10 μm. The dashed line in FIG. 2 represents an outline 34 of the adhesive layer of the laminated body to be produced later and is a non-existent line on the conductive material A.

### Production of Conductive Materials 16 to 23

Sheets of the conductive material A obtained as described above were separately immersed in treatment liquids 1 to 18, each of which contained the components shown in Table 3 in ion exchanged water. The duration and temperature of the immersion was 1 minute and 40° C., respectively. Excess metal salt-containing treatment liquid was washed off with a shower of water. After drying, conductive materials 16 to 23 were obtained. The pH of each treatment liquid used was adjusted beforehand to 7.5 with phosphoric acid, dipotassium hydrogen phosphate, or tripotassium phosphate. The amount of the copper element on the surface of each of the conductive materials 16 to 23 on the same side as the mesh pattern of metallic silver thin lines, as measured by X-ray fluorescence spectrometry, is shown in Table 4. The measurement was performed in two areas, i.e., a mesh pattern area and a non-image area, which has no mesh pattern. There was no significant difference between the two areas in any of the conductive materials.

TABLE 3

| Metal | | Component | | Component |
|---|---|---|---|---|
| salt- | | (1) | | (2) |
| containing | | concen- | | concen- |
| treatment | | tration | | tration |
| liquid | Component (1) | (mol/liter) | Component (2) | (mol/liter) |
| 11 | Copper sulfate | 0.0002 | Sodium tartrate | 0.0004 |
| | pentahydrate | | dihydrate | |
| 12 | Copper sulfate | 0.0002 | Trisodium citrate | 0.0008 |
| | pentahydrate | | dihydrate | |
| 13 | Copper sulfate | 0.0002 | Sodium DL-malate | 0.0006 |
| | pentahydrate | | hemihydrate | |
| 14 | Copper sulfate | 0.0002 | Sodium salicylate | 0.0008 |
| | pentahydrate | | | |
| 15 | Copper sulfate | 0.004 | Sodium tartrate | 0.008 |
| | pentahydrate | | dihydrate | |
| 16 | Copper sulfate | 0.004 | Trisodium citrate | 0.016 |
| | pentahydrate | | dihydrate | |
| 17 | Copper sulfate | 0.004 | Sodium DL-malate | 0.012 |
| | pentahydrate | | hemihydrate | |
| 18 | Copper sulfate | 0.004 | Sodium salicylate | 0.016 |
| | pentahydrate | | | |

TABLE 4

| Conductive | Metallic | Amount of metallic element |
|---|---|---|
| material | element | (mg/m²) |
| 16 | Cu | 2 |
| 17 | Cu | 2 |
| 18 | Cu | 2 |
| 19 | Cu | 2 |
| 20 | Cu | 5 |
| 21 | Cu | 5 |
| 22 | Cu | 5 |
| 23 | Cu | 5 |

### Production of Laminated Bodies

A sheet of each of the conductive materials 16 to 23 was laminated with the optically clear adhesive tape 8146-4 manufactured by 3M Japan Limited (then Sumitomo 3M Limited) on the area surrounded by the outline 34 shown in FIG. 2. Subsequently, the adhesive layer was laminated with EAGLE XG (registered trademark) (alkali-free glass manufactured by Corning Japan Incorporated) as a functional material. Thus, laminated bodies 16 to 23 were produced.

### Ion Migration Evaluation

One sheet of each of the laminated bodies 16 to 23 was placed in an environment of 85° C. and 85% RH, under which a voltage of 1 V was applied for 24 hours between the odd number terminals (33-1, 33-3, etc.) and even number terminals (33-2, 33-4, etc.) of each laminated body using a migration tester (MIG-8600B manufactured by IMV Corporation). Using an accessory software of the migration tester, the occurrence of short circuits between the odd number terminals and the even number terminals during the voltage application was recorded, and when a total of 10 short circuits on a conductive material laminated body occurred in the middle of the test, the voltage application thereon was made to stop automatically. After voltage application, the appearance of the peripheral wires covered with the adhesive layer was observed using a confocal microscope. The ion migration evaluation was based on the following criteria.

### Criteria for Ion Migration Evaluation

5: No short circuit occurred, and neither dissolution nor deposition of the metal was observed.
4: No short circuit occurred, but slight dissolution and deposition of the metal were observed.
3: No short circuit occurred, but dissolution and deposition of the metal were observed.
2: One to less than 10 short circuits occurred.
1: Ten short circuits occurred, and the voltage application stopped automatically in the middle of the test.

The results of the ion migration evaluation are shown in Table 5.

TABLE 5

| Conductive | | |
|---|---|---|
| material | | |
| laminated body | Ion migration evaluation | Remarks |
| 16 | 4 | Example |
| 17 | 5 | Example |
| 18 | 3 | Example |
| 19 | 2 | Example |
| 20 | 4 | Example |
| 21 | 5 | Example |
| 22 | 3 | Example |
| 23 | 2 | Example |

### Resistance Evaluation

Sheets of the conductive material 1 described above were separately immersed in the metal salt-containing treatment liquids 11 to 18 described above at 40° C. for 1 minute. As described earlier, the conductive material 1 was produced by bringing the conductive material precursor described above into close contact with the positive transparent original shown in FIG. 1, followed by light exposure, development, water washing, and drying. After the treatment, excess metal salt-containing treatment liquid was washed off with a shower of water. After drying, conductive materials 16′ to 23′ were obtained. The pattern of each of the obtained conductive materials 16′ to 23′ had the same shape and line width, etc. as those of the positive transparent original. The pH of each metal salt-containing treatment liquid used was adjusted beforehand to 7.5 with phosphoric acid, dipotassium hydrogen phosphate, or tripotassium phosphate.

### Production of Laminated Bodies

On a sheet of each of the conductive materials 16′ to 23′, a 100-μm-thick adhesive layer was formed by laminating the sheet with the optically clear adhesive tape 8146-4 manufactured by 3M Japan Limited (then Sumitomo 3M Limited) on the area 20 to be laminated with a functional material. Subsequently, the adhesive layer was laminated with EAGLE XG (registered trademark) (alkali-free glass manufactured by Corning Japan Incorporated) as a functional material. Thus, a laminated body of each conductive material was produced. The percent change in resistance (unit: %) before and after the irradiation of xenon lamp light was calculated as described above in the resistance evaluation. The percent changes in resistance for the individual test patterns 13a to 13e were averaged to determine the average percent change in resistance (unit: %) for each of the conductive materials 16′ to 23′. As a result, none of the conductive materials 16′ to 23′ showed an average percent change exceeding 2.0%.

The above results show that the addition of a hydroxy acid to a treatment liquid containing a copper metal salt is effective for reducing not only resistance change due to solar radiation exposure but also ion migration.

### REFERENCE SIGNS LIST

11 Mesh pattern
12, 12′ Fill patterns
13a to 13e Test patterns
20 Area to be laminated with a functional material
31 Sensor part
32 Peripheral wire
33 Terminal
34 Outline

1. A conductive material having a mesh pattern of metallic silver thin lines on a support, one surface of the conductive material on the same side as the mesh pattern of metallic silver thin lines being provided with a copper element in an amount of 1 mg/m² or more.

2. A treatment method for obtaining the conductive material according to claim 1, the method comprising treating, with a treatment liquid containing a copper metal salt, one surface of a conductive material in which a mesh pattern of metallic silver thin lines is provided on a support, the surface being on the same side as the mesh pattern of metallic silver thin lines.

3. The treatment method according to claim 2, wherein the treatment liquid containing a copper metal salt further contains a hydroxy acid.
